(19) United States
(12) Patent Application Publication
(10) Pub. No.: US 2008/0157884 A1
(43) Pub. Date: Jul. 3, 2008

(54) Adaptive Frequency Calibration Device of Frequency Synthesizer

(75) Inventor: Jeong Cheol Lee, Gyeonggi-do (KR)

Correspondence Address: CANTOR COLBURN, LLP, 20 Church Street, 22nd Floor, Hartford, CT, 06103, US

(73) Assignee: FCI INC., Gyeonggi-do (KR)

(21) Appl. No.: 11/993,989

(22) PCT Filed: Jul. 14, 2006
(86) PCT No.: PCT/KR2006/002766

§ 371 Date: Dec. 27, 2007

(30) Foreign Application Priority Data
Jul. 14, 2005 (KR) 10-2005-0063594

(51) Int. Cl. H03L 7/10; H03L 7/00

(52) U.S. Cl. 331/44

(57) ABSTRACT

An adaptive frequency calibration unit employing an N-target algorithm for a high speed automatic frequency calibration for CDMA application is provided. The adaptive frequency calibration device calibrating a frequency of a voltage controlled oscillator (VCO) bank of a phase-locked loop (PLL), the adaptive frequency calibration device includes: a reference frequency divider dividing an output frequency of a temperature compensated crystal oscillator (TCXO); a feedback frequency divider dividing an output frequency of a prescaler; a frequency comparator comparing a frequency with the reference frequency divider output and the feedback frequency divider output; and a state machine providing a predetermined bit with a predetermined frequency resolution for the VCO to calibrate the frequency of the VCO bank using the frequency comparison result. Accordingly, it is possible to reduce power consumption and have a small silicon region by designing the adaptive frequency calibration device using the TCXO input and the prescaler output. In addition, a short switching time, phase noise reduction, and low power consumption can be achieved.

### TECHNICAL FIELD

The present invention relates to a fractional-N frequency synthesizer with a high speed automatic frequency calibration function for code division multiple access (CDMA) application.

### BACKGROUND ART

FIG. 1 shows a fractional-N frequency synthesizer having a general adaptive frequency calibration function.

The fractional-N frequency synthesizer includes a reference frequency divider 110, a phase/frequency detector (PFD) 120, a charge pump 130, a loop filter 140, a voltage controlled oscillator (VCO) 150, an adaptive frequency control unit (AFC) 160, and a main frequency divider 170.

The reference frequency divider 110 divides a reference frequency F_{ref} by R.

The phase/frequency detector 120 compares the frequency obtained as above with an output frequency of the main frequency divider 170 and outputs the pulse string signal corresponding to the frequency difference.

The charge pump 130 pushes or pulls a current proportional to the pulse width and employs a feedback error amplifier to reduce a mismatch between the up and down currents with respect to the lower pseudo level and the noise.

The loop filter 140 filters noisy frequencies generated during a loop operation and changes a voltage of a control terminal of the VCO 150 through a variation in the accumulated charge amounts in a capacitor.

The VCO 150 outputs a specific frequency according to an input voltage.

The AFC 160, which calibrates a frequency of the VCO 150, includes a frequency detector 161 and a state machine 163.

The frequency detector 161 compares a frequency divided by n using the reference frequency divider 110 with the output frequency of the main frequency divider 170.

The state machine 163 controls VOC 150 using the compared and detected frequency.

The main frequency divider 170 inputs the output frequency of the VOC 150 for feedback and divides the output frequency by R. The main frequency divider 170, which inputs the frequency obtained as above to the PFD 120 and the frequency detector 161 of the AFC 160, includes a programmable counter 171, a prescaler 173, and a sigma-delta (Σ-Δ) modulator 175.

A conventional AFC detects a frequency using outputs of an N frequency divider and an R frequency divider.

However, since the AFC time is limited, the R frequency divider accelerates processing speed through the multiplier. However, the resolution Fᵣₑₛ of the VCO bank becomes also large, and accordingly, the VCO bank step has to become large. Therefore, it is difficult to operate normally and thus ineffective.

### DETAILED DESCRIPTION OF THE INVENTION

### Technical Goal of the Invention

An adaptive frequency calibration unit with a small VCO bank resolution employing an N-target algorithm for a high speed automatic frequency calibration for CDMA application is provided.

### DISCLOSURE OF THE INVENTION

According to an aspect of the present invention, there is provided an adaptive frequency calibration device calibrating a frequency of a voltage controlled oscillator (VCO) bank of a phase-locked loop (PLL), the adaptive frequency calibration device including: a reference frequency divider dividing an output frequency of a temperature compensated crystal oscillator (TCXO); a feedback frequency divider dividing an output frequency of a prescaler; a frequency comparator comparing a frequency with the reference frequency divider output and the feedback frequency divider output; and a state machine providing a predetermined bit with a predetermined frequency resolution for the VCO to calibrate the frequency of the VCO bank using the frequency comparison result.

### BRIEF DESCRIPTION OF THE DRAWINGS

FIG. 1 shows a frequency synthesizer having a general adaptive frequency calibration function;

FIG. 2 shows a frequency synthesizer having an adaptive frequency calibration function in order to explain the present invention;

FIG. 3 shows variation of a desired voltage controlled oscillator (VOC) bank number AFCout according to time in order to explain an operation of the present invention; and

FIG. 4 shows a waveform of a Vcon node when a CDMA channel changes from 991 (low channel) to 799 (high channel).

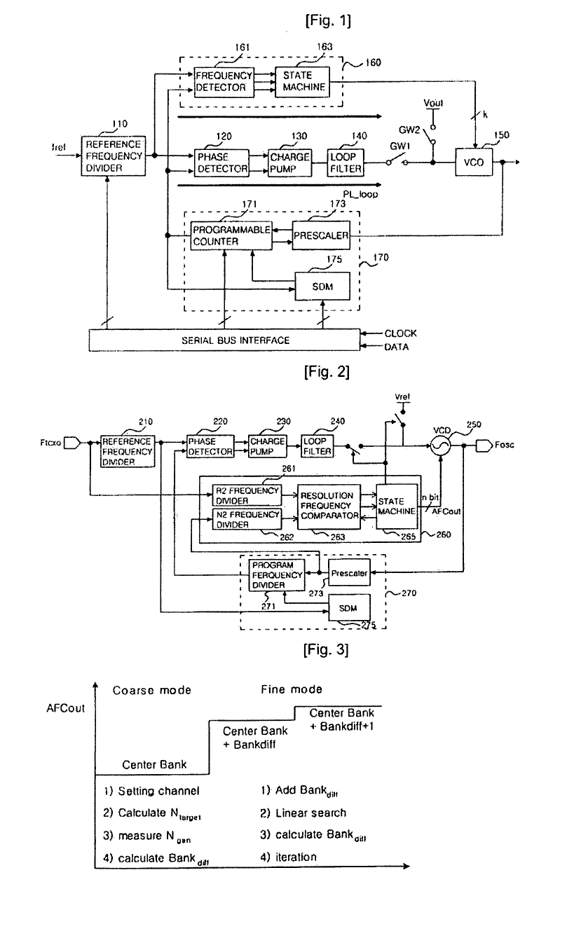

### BEST MODE FOR CARRYING OUT THE INVENTION

Hereinafter, the present will be described in detail with reference to accompanying drawings.

FIG. 3 shows a frequency synthesizer having an adaptive frequency calibration function in order to explain the present invention. The frequency synthesizer includes a reference frequency divider 210, a phase/frequency detector (PFD) 220, a charge pump 230, a loop filter 240, a voltage controlled oscillator (VCO) 250, an adaptive frequency control unit (AFC) 260, and a main frequency divider 270.

The reference frequency divider 210 divides a reference frequency of a temperature-compensated crystal oscillator (TCXO).

The PFD 220 compares the reference frequency of the TCXO divided by the reference. frequency divider 210 with the output frequency divided by the main divider 270 and outputs a pulse string signal corresponding to the frequency difference.

The charge pump 230 pushes or pulls a current proportional to the pulse width and operates a feedback error amplifier to reduce a mismatch between the up and down currents with respect to the lower pseudo level and the noise.

The loop filter 240 has a low pass filter (LPF) structure. The loop filter 240 filters noisy frequencies generated during the loop operation and changes the voltage of the control terminal of the VCO through the variation in the accumulated charge amounts using a capacitor.

The VCO 250 outputs a specific frequency according to an input voltage based on a standard negative gm topology connected to an LC tank. In the output process, n-channel metal oxide semiconductor (NMOS) and p-channel metal oxide (PMOS) cores connected to each other are used so that a negative gm reduces the phase noise. To overcome process variation, the VOC 250 includes a digital capacitor bank used for the AFC 260 that employs the N-target algorithm according to an embodiment of the present invention.

The AFC 260, which provides a predetermined bit for the VCO 250 bank, includes a reference frequency divider (R2) 261, a feedback frequency divider (N2) 262, a resolution frequency comparator 263, and a state machine 265.

The main frequency divider 270 inputs the output frequency of the VCO 250 for feedback, divides the output frequency by N, and inputs the divided frequency to the PFD 220. The main frequency divider includes a programmable frequency divider 271, a prescaler 273, and a sigma-delta (Σ-Σ) modulator 275.

Here, the sigma-delta (Σ-Δ) modulator 275 is designed to have a fourth order multistage-noise-shaping (MASH) structure with a 20-bit resolution. The MASH is selected for its high stability and good noise shaping performance.

The AFC 260 will be described in detail based on the aforementioned structure.

The numbers of reference frequency divider (R2) 261 and the feedback frequency divider (N2) 262 are determined by Equation 1 as follows, for predetermined frequency resolution and AFC locking time.

R2=F_{tcxo}·T_{comp}

N2=R2·Fᵣₑₛ/F_{tcxo} [Equation 1]

where, F_{tcxo} is a frequency of the TCXO, and T_{comp} is a time used for one comparison.

The total AFC locking time is determined by Equation 2 as follows,

$$\begin{matrix}{T}_{AFC} = {T}_{comp} \cdot {2}^{{N}_{VCObank}} ( linear search algorithm ) \\ = {T}_{comp} \cdot {N}_{VCObank} ( binary search algorithm ) \\ = {T}_{comp} \cdot K ( N \text{-} target algorithm according to \\ an embodiment of the present invention )\end{matrix} \qquad [ Equation 2 ]$$

where, N_{VCObank} is the number of VCO bank bits, and K is the repetition number of calibrations in the N-target algorithm.

The N-target value is determined by Equation 3 as follows,

$${N}_{target} = \frac{{F}_{channel} \cdot R 2}{{F}_{texo} \cdot N 2 \cdot P} \qquad [ Equation 3 ]$$

where, F_{channel} is an output channel frequency, and P is the number of prescaler frequency dividers.

FIG. 3 shows variation of a desired VCO bank number AFCout according to time in order to explain an operation of the present invention. When a channel or VCO frequency changes, the VCO bank number AFCout changes to the center bank number and then enters a coarse mode to change the VCO bank number to the sum of the center bank number and the bank difference Bankdiff. In addition, in a fine mode, the N_{gen} is compared with the N_{target}, and the VCO bank number AFCout is modified so that and the N_{gen} is equal to the N_{target}. In FIG. 3, according to the criterion for changing from the coarse mode to the fine mode, a channel setting, the N_{target}, and the N_{gen} are calculated during a first period with respect to the unit time T_{comp} to obtain the Bank_{diff}. When the Bank_{diff} is output, a Coarse_Lock signal is output at a high level, and then the coarse mode is performed during the next unit time period of T_{comp}. Since the unit time period of T_{comp} is considerably long, the Coarse_Lock is generally completed by one comparison. The final AFC Lock signal is output at a high level by performing the coarse mode two or three times after the Coarse_Lock is output at a high level. The time is referred to as AFC locking time T_{AFC}.

Hereinafter, two operation modes of the N-target algorithm will be described in more detail.

In the coarse mode, the state machine calculates the center bank number and the divided VCO output signal during the divided TCXO signal period.

Accordingly, the difference between the center bank and the VCO bank is calculated by Equation 4 shown below.

$${Bank}_{diff} = \frac{{F}_{res}}{{F}_{step}} \times ( {N}_{gen} - {N}_{target} ) \qquad [ Equation 4 ]$$

In the coarse mode, the VCO bank number is determined by adding the VCO bank difference to the center bank number.

In the fine mode, the desired VCO bank number is determined by using a linear search algorithm to correct the bank error due to the VCO gain slope and variation of the frequency step of the bank.

K is an approximated first order search measuring number between 1 and 3. When the VCO includes a large number of banks, the N-target algorithm has a short AFC locking time, since the N-target algorithm is not sensitive to the number of banks. The AFC is designed using the TCXO input which is used in the main loop and the output of the prescaler, for low power consumption and a small silicon region.

Accordingly, F_{tcxo} is input and the output of the prescaler 273 is input in order to reduce the Fᵣₑₛ, power consumption, and a size of hardware.

The Tres is determined by Tᵣₑₛ=F_{tcxo}*(P*N/2)/R2. The reference frequency divider 261 and the processing speed are dominantly determined by the resolution.

Since Fᵣₑₛ and F_{target} (target frequency: Fᵣₑₛ*Nₜₐᵣ) are known, it is possible to move to the desired bank at once by comparing the practically desired Nₜₐᵣ with the countered value.

When the VCO is designed, Fₛₜₑₚ is irregular and an error exists. The error is corrected together with a linear search in the end of the process.

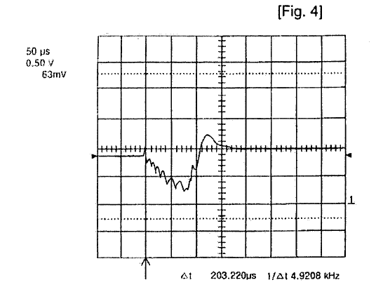

FIG. 4 shows a waveform of a Vcon node when a CDMA channel changes from 991 (low channel) to 799 (high channel).

Total time of the AFC time (Fᵣₑₛ=4.8 MHz) and the entire locking time is about 200 μsec (BW=15 KHz).

While the present invention has been particularly shown and described with reference to exemplary embodiments thereof, it will be understood by those skilled in the art that various changes in form and details may be made therein without departing from the spirit and scope of the present invention as defined by the appended claims.

### INDUSTRIAL APPLICABILITY

According, to the present invention, it is possible to reduce power consumption and have a small silicon region by designing the adaptive frequency calibration device using the TCXO input and the prescaler output.

In addition, a short switching time, phase noise reduction, and low power consumption can be achieved.

1. An adaptive frequency calibration device calibrating a frequency of a VCO (voltage controlled oscillator) bank of a PLL (phase-locked loop), the adaptive frequency calibration device comprising:
a reference frequency divider dividing an output frequency of a TCXO (temperature compensated crystal oscillator);
a feedback frequency divider dividing an output frequency of a prescaler;
a frequency comparator comparing a frequency with outputs of the reference frequency divider and the feedback frequency divider; and
a state machine providing a predetermined bit with a predetermined frequency resolution for the VCO in order to calibrate the frequency of the VCO bank using the frequency comparison result.

2. The adaptive frequency calibration device of claim 1, wherein the numbers of the reference frequency divider and the feedback frequency divider are determined by the following equations:
R2=F_{tcxo}·T_{comp}
N2=R2·Rᵣₑₛ/F_{tcxo}
where, F_{tcxo} is a frequency of the TCXO, and T_{comp} is a time used for one comparison.

3. The adaptive frequency calibration device of claim 1, wherein, in a coarse mode, the state machine calculates the center bank number and a divided VCO output signal during the divided TCXO signal period.

4. The adaptive frequency calibration device of claim 3, wherein the difference between the center bank and the VCO bank is calculated by the following equation:
$${Bank}_{diff} = \frac{{F}_{res}}{{F}_{step}} \times ( {N}_{gen} - {N}_{target} ) .$$

5. The adaptive frequency calibration device of claim 4, wherein, in the coarse mode, the VCO bank number is determined by adding the VCO bank difference to the center bank number.

6. The adaptive frequency calibration device of claim 4, wherein, in the fine mode, the desired VCO bank number is determined by using a linear search algorithm to correct the bank error due to the VCO gain slope and variation of the frequency step of the bank.
